(19) United States
(12) Patent Application Publication
(10) Pub. No.: US 2026/0071151 A1
(43) Pub. Date: Mar. 12, 2026

(54) THINNER COMPOSITION, METHOD FOR SUBSTRATE PROCESSING AND MODIFIED PHOTORESIST

(71) Applicant: Advanced Echem Materials Company Limited, Taoyuan (TW)

(72) Inventors: Chen-Jing Guo, Taoyuan (TW); Shan Lu, Taoyuan (TW); Yi-Han Hsu, Taoyuan (TW)

(73) Assignee: Advanced Echem Materials Company Limited, Taoyuan (TW)

(21) Appl. No.: 19/315,640

(22) Filed: Aug. 31, 2025

(30) Foreign Application Priority Data
Sep. 12, 2024 (TW) 113134549

(51) Int. Cl. C11D 7/28; C11D 7/26; C11D 7/50; G03F 7/075; G03F 7/42

(52) U.S. Cl. CPC C11D 7/28; C11D 7/263; C11D 7/5022; G03F 7/0751; G03F 7/0757; G03F 7/426; C11D 2111/22

(57) ABSTRACT

A thinner composition, a method for substrate processing and a modified photoresist are provided. The thinner composition includes a solvent (A), a fluorine-containing additive (B) and a polyether polyol (C). The fluorine-containing additive (B) includes a polymer represented by the following Formula (B-1), a polymer represented by the following Formula (B-2), a polymer represented by the following Formula (B-3), a polymer represented by the following Formula (B-4), or a combination thereof. The polyether polyol (C) includes a polymer represented by following Formula (C-1). A ratio of a usage amount of the fluorine-containing additive (B) to a usage amount of the polyether polyol (C) is 2:1 to 1:4. Based on 100 parts by weight of the thinner composition, a usage amount of the fluorine-containing additive (B) is 0.001 parts by weight to 2 parts by weight, a usage amount of the polyether polyol (C) is 0.001 parts by weight to 2 parts by weight.

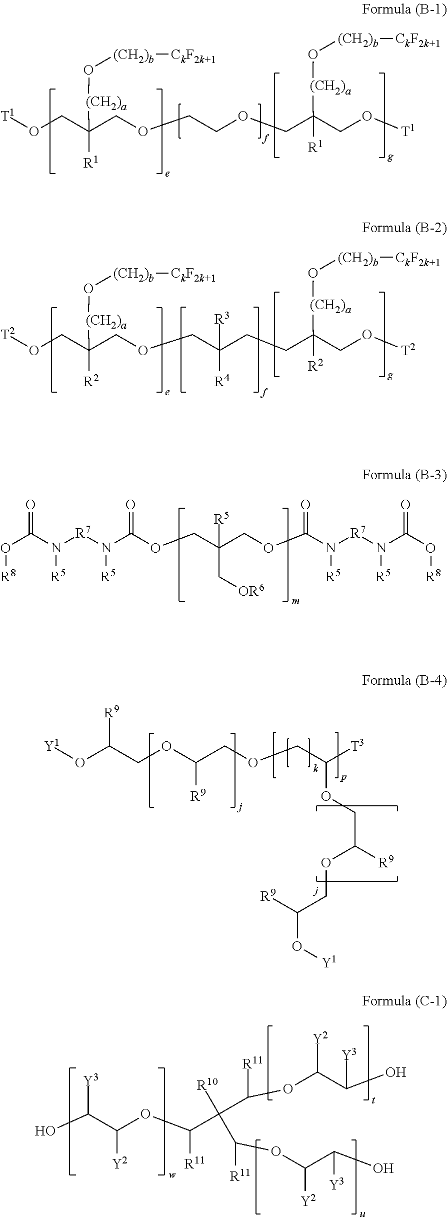

In Formula (B-1), Formula (B-2), Formula (B-3), Formula (B-4) and Formula (C-1), the definition of R¹ to R¹¹, T¹ to T³, Y¹ to Y³, a, b, e, f, g, j, k, m, p, t, u and w are the same as the definition thereof in the specification.

### CROSS-REFERENCE TO RELATED APPLICATION

This application claims the priority benefit of Taiwan application serial no. 113134549, filed on Sep. 12, 2024. The entirety of the above-mentioned patent application is hereby incorporated by reference herein and made a part of this specification.

### BACKGROUND

### Technical Field

The present invention relates to a thinner composition, and particularly relates to a thinner composition, a method for substrate processing, and a modified photoresist.

### Description of Related Art

With the vigorous development of semiconductor devices, display devices, or optical elements, in order to expand their application scope, the demand for performance and quality has gradually increased. For example, in the manufacturing process of semiconductor devices, an edge bead remover including an additive is typically used to clean the edge of the wafer. However, the additive in the edge bead remover often remains on the edge of the substrate after cleaning, causing phenomenon such as irregular stacking due to photoresist slipping in subsequent manufacturing processes, thereby affecting the performance of the manufactured devices.

### SUMMARY

The invention provides a thinner composition, a method for substrate processing, and a modified photoresist capable of providing good adhesion, which may effectively remove protrusions on the edge of the substrate and may effectively clean the edge of the substrate.

The invention provides a thinner composition. The thinner composition includes a solvent (A), a fluorine-containing additive (B), and a polyether polyol (C). The fluorine-containing additive (B) includes a polymer represented by the following Formula (B-1), a polymer represented by the following Formula (B-2), a polymer represented by the following Formula (B-3), a polymer represented by the following Formula (B-4), or a combination thereof. The polyether polyol (C) includes a polymer represented by the following Formula (C-1). A ratio of a usage amount of the fluorine-containing additive (B) to a usage amount of the polyether polyol (C) is 2:1 to 1:4. Based on 100 parts by weight of the thinner composition, a usage amount of the fluorine-containing additive (B) is 0.001 parts by weight to 2 parts by weight, a usage amount of the polyether polyol (C) is 0.001 parts by weight to 2 parts by weight.

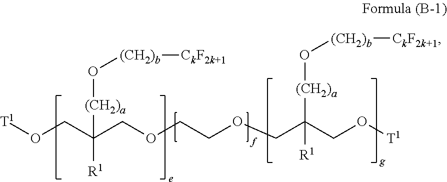

In Formula (B-1), R¹ represents hydrogen, fluorine, a hydroxyl group, an alkyl group with 1 to 3 carbon atoms, or a fluoroalkyl group with 1 to 2 carbon atoms,
T¹ represents hydrogen, an alkyl group with 1 to 3 carbon atoms, *—COCH₃, *—COC₂H₅, *—SO₃H, *—SO₃NH₄, *—SO₃Na or *—SO₃K,
a represents an integer of 1 to 3,
b represents an integer of 1 to 5,
e represents an integer of 1 to 8,
f represents an integer of 10 to 30,
g represents an integer of 2 to 10,
k represents an integer of 1 to 5;

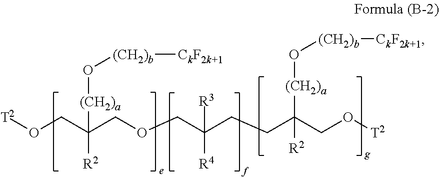

In Formula (B-2), R² represents hydrogen, fluorine, a hydroxyl group, an alkyl group with 1 to 3 carbon atoms, or a fluoroalkyl group with 1 to 2 carbon atoms,
R³ represents hydrogen, a hydroxyl group, a carboxyl group, an alkyl group with 1 to 3 carbon atoms, *—COCH₃, *—COC₂H₅, *—SO₃H, *—SO₃NH₄, *—SO₃Na or *—SO₃K,
R⁴ represents hydrogen, a hydroxyl group, an alkyl group with 1 to 2 carbon atoms, or an alkoxy group with 1 to 2 carbon atoms,
T² represents hydrogen, an alkyl group with 1 to 3 carbon atoms, *—COCH₃, *—COC₂H₅, *—SO₃H, *—SO₃NH₄, *—SO₃Na or *—SO₃K,
a represents an integer of 1 to 3,
b represents an integer of 1 to 5,
f represents an integer of 1 to 20,
k represents an integer of 1 to 6,
a sum of e and g is an integer of 17 to 30;

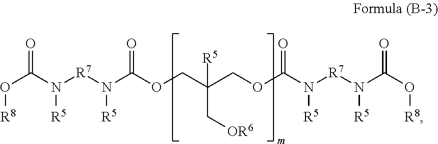

In Formula (B-3), R⁵ represents hydrogen, an alkyl group with 1 to 3 carbon atoms, or an alkoxy group with 1 to 3 carbon atoms,
R⁶ represents a fluoroalkyl group with 1 to 4 carbon atoms,
R⁷ represents CₙH₂ₙ₋₂, wherein n represents an integer of 4 to 20,
R⁸ represents C_{y}H_{2y-3}O_{z}, wherein y represents an integer of 4 to 20, z represents an integer of 0 to 5,
m represents an integer of 2 to 30;

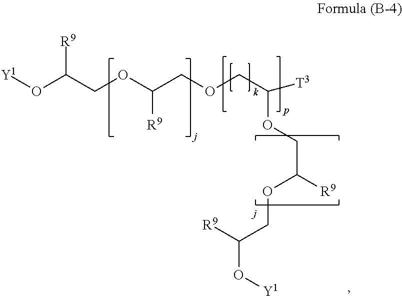

In Formula (B-4), Y¹ represents CᵣF₂ᵣ₋₁, wherein r represents an integer of 2 to 15,
R⁹ represents hydrogen, a hydroxyl group, an alkyl group with 1 to 3 carbon atoms, or an alkoxy group with 1 to 3 carbon atoms,
T³ represents hydrogen, an alkyl group with 1 to 3 carbon atoms, an alkoxy group with 1 to 3 carbon atoms, a hydroxyl group, a carboxyl group, *—COOCH₃, *—COOC₂H₅, an aldehyde group, an amino group, *—OSO₃H, *—OSO₃NH₄, *—OSO₃Na or *—OSO₃K,
j represents an integer of 2 to 30,
k represents an integer of 0 to 20,
p represents an integer of 1 to 9;

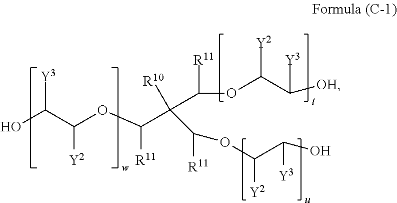

In Formula (C-1), R¹⁰ represents hydrogen, an alkyl group with 1 to 5 carbon atoms, an alkoxy group with 1 to 5 carbon atoms, a hydroxyl group, a carboxyl group, *—COOCH₃, *—COOC₂H₅, an aldehyde group, an amino group, *—OSO₃H, *—OSO₃NH₄, *—OSO₃Na or *—OSO₃K,
R¹¹ represents hydrogen, a hydroxyl group or an alkyl group with 1 to 5 carbon atoms,
Y² represents hydrogen, a hydroxyl group, an alkyl group with 1 to 6 carbon atoms or an alkoxy group with 1 to 6 carbon atoms,
Y³ represents hydrogen, a hydroxyl group, an alkyl group with 1 to 8 carbon atoms or an alkoxy group with 1 to 8 carbon atoms,
t represents an integer of 10 to 600,
u represents an integer of 10 to 700,
w represents an integer of 10 to 800,
wherein * represents a bonding position.

In an embodiment of the invention, the solvent (A) includes propylene glycol monomethyl ether, propylene glycol monomethyl ether acetate, n-butyl acetate, N-methyl-2-pyrrolidone, isopropanol, 4-methyl-2-pentanol, γ-butyrolactone, cyclohexanone, cyclohexanol, dimethyl sulfoxide, ethanol, methanol, butanol, or a combination thereof.

In an embodiment of the invention, the solvent (A) is a mixed solvent. The mixed solvent is composed by mixing at least two different organic solvents.

In an embodiment of the invention, the solvent (A) includes propylene glycol monomethyl ether, and further includes at least one of propylene glycol monomethyl ether acetate, n-butyl acetate, N-methyl-2-pyrrolidone, isopropanol, 4-methyl-2-pentanol, γ-butyrolactone, cyclohexanone, cyclohexanol, dimethyl sulfoxide, ethanol, methanol, and butanol.

In an embodiment of the invention, the solvent (A) is a mixed solvent composed by mixing propylene glycol monomethyl ether and n-butyl acetate. A mixing ratio of propylene glycol monomethyl ether to n-butyl acetate is 10:90 to 40:60.

In an embodiment of the invention, the solvent (A) is a mixed solvent composed by mixing propylene glycol monomethyl ether and propylene glycol monomethyl ether acetate. A mixing ratio of propylene glycol monomethyl ether to propylene glycol monomethyl ether acetate is 50:50 to 80:20.

In an embodiment of the invention, a weight average molecular weight of the polymer represented by Formula (B-1) is 1000 to 5000, a weight average molecular weight of the polymer represented by Formula (B-2) is 2000 to 9000, a weight average molecular weight of the polymer represented by Formula (B-3) is 1500 to 8500, a weight average molecular weight of the polymer represented by Formula (B-4) is 1000 to 15000.

In an embodiment of the invention, a weight average molecular weight of the polymer represented by Formula (C-1) is 4000 to 25000.

A method for substrate processing of the invention includes applying the thinner composition described above to a substrate surface.

In an embodiment of the invention, the thinner composition is applied to an edge of the substrate surface.

In an embodiment of the invention, a photoresist composition has been coated on the substrate surface. The thinner composition removes a protrusion on an edge of the surface of the photoresist composition.

A modified photoresist of the invention includes a photoresist, the fluorine-containing additive (B) described above, and the polyether polyol (C) described above. A ratio of a usage amount of the fluorine-containing additive (B) to a usage amount of the polyether polyol (C) is 2:1 to 1:4. Based on 100 parts by weight of the modified photoresist, a usage amount of the fluorine-containing additive (B) is 0.001 parts by weight to 2 parts by weight, a usage amount of the polyether polyol (C) is 0.001 parts by weight to 2 parts by weight.

Based on the above, the thinner composition and the modified photoresist of the invention each include a fluorine-containing additive (B) with a specific structure and a polyether polyol (C) with a specific structure, respective usage amounts thereof within a specific range and the usage amounts of both within a specific ratio range. Thus, when the thinner composition is used in a method for substrate processing, it may have good adhesion, good removal of protrusions on the edge of the substrate, and good cleaning of the edge of the substrate, and may enable the surface of the modified photoresist to have good hydrophilicity and thus good adhesion.

To make the above-mentioned features and advantages of the present invention more evident and comprehensible, embodiments are described in detail below.

### DESCRIPTION OF THE EMBODIMENTS

### <Thinner Composition>

The invention provides a thinner composition including a solvent (A), a fluorine-containing additive (B) and a polyether polyol (C). In addition, the thinner composition of the invention may further include other suitable additives as needed. The components are described hereinafter in detail.

### Solvent (A)

The solvent (A) is not particularly limited, and any suitable solvent may be selected according to needs. For example, the solvent (A) may include propylene glycol monomethyl ether, propylene glycol monomethyl ether acetate, n-butyl acetate, N-methyl-2-pyrrolidone, isopropanol, 4-methyl-2-pentanol, γ-butyrolactone, cyclohexanone, cyclohexanol, dimethyl sulfoxide, ethanol, methanol, butanol, a combination thereof, or other suitable solvents.

In this embodiment, the solvent (A) may preferably be a mixed solvent. The mixed solvent may be composed by mixing at least two different organic solvents. A boiling point of the mixed solvent may be 70° C. to 170° C., preferably 90° C. to 150° C. A turbidity of the mixed solvent may be less than or equal to 0.02 NTU, preferably 0.001 NTU to 0.01 NTU. The solvent (A) may preferably be a mixed solvent composed by mixing propylene glycol monomethyl ether and other solvents. For example, the solvent (A) may include propylene glycol monomethyl ether, and may further include at least one of propylene glycol monomethyl ether acetate, n-butyl acetate, N-methyl-2-pyrrolidone, isopropanol, 4-methyl-2-pentanol, γ-butyrolactone, cyclohexanone, cyclohexanol, dimethyl sulfoxide, ethanol, methanol, and butanol. In this embodiment, the solvent (A) may preferably be a mixed solvent composed by mixing propylene glycol monomethyl ether and n-butyl acetate or a mixed solvent composed by mixing propylene glycol monomethyl ether and propylene glycol monomethyl ether acetate.

In the mixed solvent composed by mixing propylene glycol monomethyl ether and n-butyl acetate, a mixing ratio of propylene glycol monomethyl ether to n-butyl acetate may be 10:90 to 40:60, preferably 20:80 to 40:60. For example, when the mixing ratio of propylene glycol monomethyl ether to n-butyl acetate is 20:80, its turbidity is about 0.003 NTU. When the mixing ratio of propylene glycol monomethyl ether to n-butyl acetate is 40:60, its turbidity is about 0.003 NTU.

In the mixed solvent composed by mixing propylene glycol monomethyl ether and propylene glycol monomethyl ether acetate, a mixing ratio of propylene glycol monomethyl ether to propylene glycol monomethyl ether acetate may be 50:50 to 80:20, preferably 65:35 to 75:25. For example, when the mixing ratio of propylene glycol monomethyl ether to propylene glycol monomethyl ether acetate is 70:30, its turbidity is about 0.003 NTU.

When the thinner composition includes a solvent (A), the thinner composition may have a suitable viscosity, thereby allowing the thinner composition to be applied well to the substrate surface in order to effectively remove protrusions on the edge of the substrate.

### Fluorine-Containing Additive (B)

The fluorine-containing additive (B) includes a polymer represented by the following Formula (B-1), a polymer represented by the following Formula (B-2), a polymer represented by the following Formula (B-3), a polymer represented by the following Formula (B-4), or a combination thereof. The fluorine-containing additive (B) may further include other suitable fluorine-containing additives.

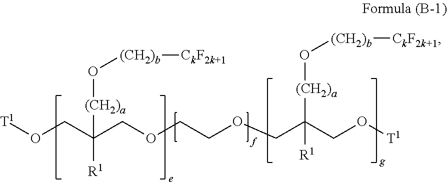

In Formula (B-1),
R¹ represents hydrogen, fluorine, a hydroxyl group, an alkyl group with 1 to 3 carbon atoms, or a fluoroalkyl group with 1 to 2 carbon atoms, preferably hydrogen, a methyl group, or a fluoromethyl group;
T¹ represents hydrogen, an alkyl group with 1 to 3 carbon atoms, *—COCH₃, *—COC₂H₅, *—SO₃H, *—SO₃NH₄, *—SO₃Na or *—SO₃K, preferably hydrogen, a methyl group, or an ethyl group;
a represents an integer of 1 to 3, preferably an integer of 1 to 2;
b represents an integer of 1 to 5, preferably an integer of 1 to 3;
e represents an integer of 1 to 8, preferably an integer of 1 to 5;
f represents an integer of 10 to 30, preferably an integer of 16 to 24;
g represents an integer of 2 to 10, preferably an integer of 2 to 5; and
k represents an integer of 1 to 5, preferably an integer of 2 to 4,
wherein * represents a bonding position.

In Formula (B-1), a plurality of R¹ are the same as or different from each other, a plurality of T¹ are the same as or different from each other, a plurality of a are the same as or different from each other, a plurality of b are the same as or different from each other, a plurality of k are the same as or different from each other.

A weight average molecular weight of the polymer represented by Formula (B-1) may be 1000 to 5000, preferably 1300 to 3200.

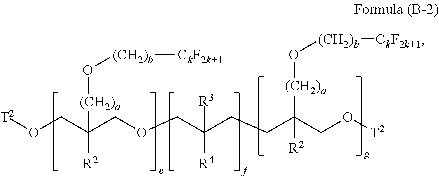

In Formula (B-2),
R² represents hydrogen, fluorine, a hydroxyl group, an alkyl group with 1 to 3 carbon atoms, or a fluoroalkyl group with 1 to 2 carbon atoms, preferably hydrogen, a methyl group, or a fluoromethyl group;
R³ represents hydrogen, a hydroxyl group, a carboxyl group, an alkyl group with 1 to 3 carbon atoms, *—COCH₃, *—COC₂H₅, *—SO₃H, *—SO₃NH₄, *—SO₃Na or *—SO₃K, preferably hydrogen, a methoxy group, a methyl group, or an ethyl group;
R⁴ represents hydrogen, a hydroxyl group, an alkyl group with 1 to 2 carbon atoms, or an alkoxy group with 1 to 2 carbon atoms, preferably hydrogen, a methyl group, an ethyl group, a methoxy group, or an ethoxy group;
T² represents hydrogen, an alkyl group with 1 to 3 carbon atoms, *—COCH₃, *—COC₂H₅, *—SO₃H, *—SO₃NH₄, *—SO₃Na or *—SO₃K, preferably hydrogen, a methyl group, or an ethyl group;
a represents an integer of 1 to 3, preferably an integer of 1 to 2;
b represents an integer of 1 to 5, preferably an integer of 1 to 3;
f represents an integer of 1 to 20, preferably an integer of 1 to 5;
k represents an integer of 1 to 6, preferably an integer of 2 to 4; and
a sum of e and g is an integer of 17 to 30, preferably an integer of 18 to 25; wherein e may represent an integer of 2 to 15, preferably an integer of 4 to 13; g may represent an integer of 2 to 15, preferably an integer of 4 to 13,
wherein * represents a bonding position.

In Formula (B-2), a plurality of R² are the same as or different from each other, a plurality of T² are the same as or different from each other, a plurality of a are the same as or different from each other, a plurality of b are the same as or different from each other, a plurality of k are the same as or different from each other. When f is an integer of 2 or greater, a plurality of R³ are the same as or different from each other, a plurality of R⁴ are the same as or different from each other.

A weight average molecular weight of the polymer represented by Formula (B-2) may be 2000 to 9000, preferably 3700 to 5700.

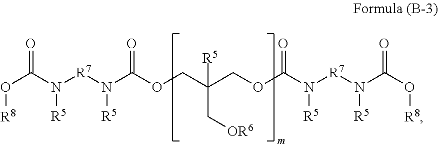

In Formula (B-3),
R⁵ represents hydrogen, an alkyl group with 1 to 3 carbon atoms, or an alkoxy group with 1 to 3 carbon atoms, preferably hydrogen, a methyl group, an ethyl group, a methoxy group, or an ethoxy group;
R⁶ represents a fluoroalkyl group with 1 to 4 carbon atoms, preferably fluoromethyl (CF₃), difluoroethyl (for example, CH₂CF₂H), trifluoroethyl (for example, CH₂CF₃), pentafluoroethyl (for example, C₂F₅), tetrafluoroethyl (for example, C₂F₄H), or pentafluoropropyl (for example, CH₂C₂F₅);
R⁷ represents CₙH₂ₙ₋₂, wherein n represents an integer of 4 to 20, preferably an integer greater than 4 and less than 20 (i.e., an integer of 5 to 19), more preferably an integer of 8 to 13;
R⁸ represents C_{y}H_{2y-3}O_{z}, wherein y represents an integer of 4 to 20, preferably an integer greater than 4 and less than 20 (i.e., an integer of 5 to 19), more preferably an integer of 5 to 9; z represents an integer of 0 to 5, preferably an integer greater than 0 and less than 5 (i.e., an integer of 1 to 4), more preferably an integer of 2 to 3; and
m represents an integer of 2 to 30, preferably an integer greater than 2 and less than 30 (i. e., an integer of 3 to 29), more preferably an integer of 15 to 25.

In Formula (B-3), a plurality of R⁵ are the same as or different from each other, a plurality of R⁷ are the same as or different from each other, a plurality of R⁸ are the same as or different from each other. When m is an integer of 2 or greater, a plurality of R⁶ are the same as or different from each other.

In this embodiment, R⁸ in Formula (B-3) may preferably be an oxyalkenyl group (for example, 1,3-butadiene ethoxy group, 1,4-pentadiene methoxy group), an ester alkenyl group (for example, ethyl acrylate group, methyl butenoate group, propyl ethenylate group), or a cycloalkoxy group (for example, cyclohexanone methoxy group, cyclopentanone ethoxy group). R⁷ includes a ring or an unsaturated bond (for example, cycloalkyl group, alkenyl group, cycloalkylene group, or alkenylene group), preferably including a cycloalkyl group or a cycloalkylene group. R⁷ is preferably an alkenylene group (for example,

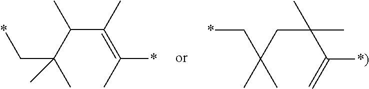

or a cycloalkylene group (for example,

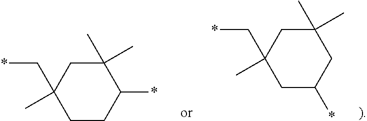 [SMILES: *CC1(C)CCC(*)C(C)(C)C1 ; *CC1(C)CC(*)CC(C)(C)C1]

* represents a bonding position.

A weight average molecular weight of the polymer represented by Formula (B-3) may be 1500 to 8500, preferably 3000 to 5500.

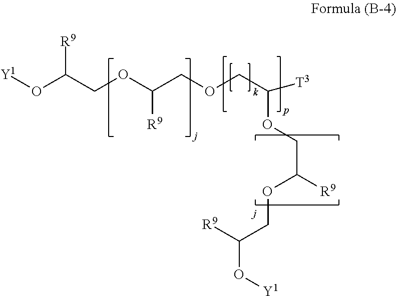

In Formula (B-4),
Y¹ represents CᵣF₂ᵣ₋₁, wherein r represents an integer of 2 to 15, preferably an integer of 3 to 12;
R⁹ represents hydrogen, a hydroxyl group, an alkyl group with 1 to 3 carbon atoms, or an alkoxy group with 1 to 3 carbon atoms, preferably hydrogen, a methyl group, an ethyl group, a methoxy group, or an ethoxy group;
T³ represents hydrogen, an alkyl group with 1 to 3 carbon atoms, an alkoxy group with 1 to 3 carbon atoms, a hydroxyl group, a carboxyl group, *—COOCH₃, *—COOC₂H₅, an aldehyde group (*—CHO), an amino group (for example, *—NH₂), *—OSO₃H, *—OSO₃NH₄, *—OSO₃Na or *—OSO₃K, preferably hydrogen, a methyl group, an ethyl group, a methoxy group, an ethoxy group, or a hydroxyl group;
j represents an integer of 2 to 30, preferably an integer of 2 to 20;
k represents an integer of 0 to 20, preferably an integer of 2 to 13; and
p represents an integer of 1 to 9, preferably an integer of 1 to 5,
wherein * represents a bonding position.

In Formula (B-4), a plurality of Y¹ are the same as or different from each other, a plurality of R⁹ are the same as or different from each other, a plurality of j are the same as or different from each other. When p is an integer of 2 or greater, a plurality of k are the same as or different from each other.

In this embodiment, Y¹ in Formula (B-4) may include a ring or an unsaturated bond (for example, cycloalkyl group, alkenyl group, cycloalkylene group, or alkenylene group), preferably including an alkenyl group or an alkenylene group. Y¹ may preferably be a fluorine-containing cycloalkyl group (for example, 1-(1,1,1-trifluoromethyl)-1,2,2,3,3,4,5,5,6,6-decafluorocyclohexane-4,4-difluoromethyl group, 1,2,2,3,4,5,5-heptafluorocyclopentane-3,4-bis(trifluoromethyl)-1-(1,1,2,2,3,3-hexafluoropropyl) group, 1,2,2,3,4,4,5,6,6-nonafluorocyclohexane-3,5-bis(trifluoromethyl)-1-(1,1,2,2,3,3-hexafluoropropyl)) group or fluorine-containing alkenyl group (for example, 4-perfluoroisopropyl-2,5-bis(trifluoromethyl)-1,1,1,2,5,6,6,6-octafluoro-3-hexenyl group, 3-perfluoropropyl-5-trifluoromethyl-1,1,1,4,4,5,6,6,6-nonafluoro-2-hexenyl group, 3-perfluoroisopropyl-4-trifluoromethyl-1,1,1,4,5,5,5-heptafluoro-2-pentenyl group, 3-perfluoroethyl-1,1,1,4,4,5,5,6,6,6-decafluoro-2-hexenyl group) or fluorine-containing alkenylene group (for example, 3,4-perfluoroethyl-1,1,1,2,2,5,6,6,7,7,7-undecafluoro-3-heptenyl group, 3,4-perfluoroethyl-1,1,1,2,2,5,6,6,6-nonafluoro-3-hexenyl group, 3-perfluoroethyl-4-difluoromethyl-1,1,2,3,4,5,5,6,6,6-decafluoro-1-hexenyl group, 3-perfluoroethyl-1,1,1,2,2,4,5,5,6,6-decafluoro-3-hexenyl group).

A weight average molecular weight of the polymer represented by Formula (B-4) may be 1000 to 15000, preferably 1500 to 4500.

Based on 100 parts by weight of the thinner composition, a usage amount of the fluorine-containing additive (B) is 0.001 parts by weight to 2 parts by weight, preferably 0.002 parts by weight to 0.6 parts by weight.

When the thinner composition includes a fluorine-containing additive (B) with a specific structure, the thinner composition may effectively remove protrusions from the edge of the substrate when the thinner composition is used in a method for substrate processing. For example, when a photoresist composition is coated on the substrate surface and protrusions are present at the edge of the photoresist composition surface, the fluorine-containing additive (B) with a specific structure may reduce the intermolecular force between polymers in the photoresist composition, thereby reducing the phenomenon of protrusion formation at the edge of the surface of the photoresist formed by the photoresist composition, thus effectively removing protrusions from the edge of the substrate.

### Polyether Polyol (C)

The polyether polyol (C) includes a polymer represented by the following Formula (C-1). The polyether polyol (C) may further include other suitable polyether polyols.

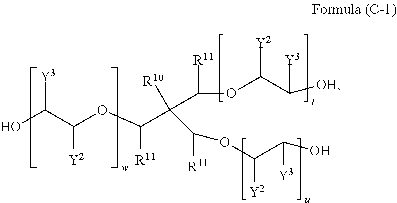

In Formula (C-1),
R¹⁰ represents hydrogen, an alkyl group with 1 to 5 carbon atoms, an alkoxy group with 1 to 5 carbon atoms, a hydroxyl group, a carboxyl group, *—COOCH₃, *—COOC₂H₅, an aldehyde group (*—CHO), an amino group (for example, *—NH₂), *—OSO₃H, *—OSO₃NH₄, *—OSO₃Na or *—OSO₃K, preferably hydrogen, a methyl group, an ethyl group, a methoxy group, or an ethoxy group;
R¹¹ represents hydrogen, a hydroxyl group or an alkyl group with 1 to 5 carbon atoms, preferably hydrogen, a methyl group or an ethyl group;
Y² represents hydrogen, a hydroxyl group, an alkyl group with 1 to 6 carbon atoms or an alkoxy group with 1 to 6 carbon atoms, preferably hydrogen, a methyl group or an ethyl group;
Y³ represents hydrogen, a hydroxyl group, an alkyl group with 1 to 8 carbon atoms or an alkoxy group with 1 to 8 carbon atoms, preferably hydrogen, a methyl group or an ethyl group;
t represents an integer of 10 to 600, preferably an integer of 20 to 150;
u represents an integer of 10 to 700, preferably an integer of 20 to 200; and
w represents an integer of 10 to 800, preferably an integer of 20 to 250,
wherein * represents a bonding position.

In Formula (C-1), a plurality of R¹¹ are the same as or different from each other, a plurality of Y² are the same as or different from each other, a plurality of Y³ are the same as or different from each other.

A weight average molecular weight of the polymer represented by Formula (C-1) is 4000 to 25000, preferably 5000 to 13000.

Based on 100 parts by weight of the thinner composition, a usage amount of the polyether polyol (C) is 0.001 parts by weight to 2 parts by weight, preferably 0.01 parts by weight to 1.2 parts by weight.

When the thinner composition includes a polyether polyol (C) with a specific structure, the thinner composition may have good adhesion when the thinner composition is used in a method for substrate processing. For example, when a first layer of a photoresist layer is formed on the substrate surface, the thinner composition may be removed during the baking process, which may reduce the residue of the thinner composition at the edge of the substrate surface, allowing a subsequently formed second layer of the photoresist layer on the first layer of the photoresist layer to have good adhesion with the first layer of the photoresist layer.

A ratio of a usage amount of the fluorine-containing additive (B) to a usage amount of the polyether polyol (C) is 2:1 to 1:4, preferably 1:2 to 1:4. That is, a quotient of the ratio of the usage amount of the fluorine-containing additive (B) to the usage amount of the polyether polyol (C) is 0.25 to 2, preferably about 0.25 to 0.5. When the thinner composition includes a specific ratio of the fluorine-containing additive (B) with a specific structure to the polyether polyol (C) with a specific structure, the thinner composition may have good adhesion and good removal of protrusions at the edge of the substrate when the thinner composition is used in a method for substrate processing.

### <Method for Preparing Thinner Composition>

The method for preparing the thinner composition is not particularly limited. For example, the solvent (A), the fluorine-containing additive (B) and the polyether polyol (C) are placed in a mixer and stirred to be mixed uniformly into a solution state. Other suitable additives may also be added if necessary. After mixing them uniformly, a liquid thinner composition may be obtained.

### <Method for Substrate Processing>

An exemplary embodiment of the invention provides a method for substrate processing that includes applying the thinner composition described above to a substrate surface.

For example, the method for substrate processing may include: applying a photoresist composition to a substrate surface, and the protrusions may form at the edge of the substrate surface; applying the thinner composition to the substrate surface, particularly to the edge of the substrate surface; and removing the protrusions from the edge of the surface.

In this embodiment, the photoresist composition may be firstly coated to the substrate surface, and then the thinner composition is applied to the surface of the photoresist composition. For example, when the photoresist composition is coated to the substrate surface, the photoresist composition easily forms protrusions at the edge of the substrate surface, that is, protrusions formed at the edge of the photoresist surface. Therefore, it may be preferable to apply the thinner composition to the edge of the substrate surface or the edge of the photoresist surface.

The substrate may be a wafer, a glass substrate, a plastic base material (for example, polyethersulfone (PES) plate, polycarbonate (PC) plate, or polyimide (PI) film), or other light-transmitting substrate, and the type thereof is not particularly limited.

The photoresist composition may be a positive-type photoresist composition or a negative-type photoresist composition. The positive-type photoresist composition may include a resin, a photosensitizer, a monomer, a solvent, or other suitable additives. The negative-type photoresist composition may include a resin, a photoinitiator, a monomer, a solvent, or other suitable additives.

The method of coating the photoresist composition to the substrate surface is not particularly limited, but a spray coating method, a roll coating method, a spin coating method, or the like may be used, and in general, a spin coating method is widely used.

The method of applying the thinner composition to the substrate surface or photoresist composition surface is not particularly limited, and in general, a spray coating method is widely used.

### <Modified Photoresist>

An exemplary embodiment of the invention provides a modified photoresist including a photoresist, the fluorine-containing additive (B) described above, and the polyether polyol (C) described above.

The photoresist may be a positive-type photoresist or a negative-type photoresist, and a suitable photoresist may be selected according to needs. The photoresist may be formed by a photoresist composition, wherein the photoresist composition may be a positive-type photoresist composition or a negative-type photoresist composition.

In this embodiment, since the description of the fluorine-containing additive (B) and the polyether polyol (C) in the modified photoresist may be the same as the fluorine-containing additive (B) and the polyether polyol (C) in the thinner composition described above, they will not be described in detail here.

The invention is described hereinafter in detail with reference to some examples. The following examples are provided to describe the invention, and the scope of the invention includes the categories described in the following claims, their equivalents, and their modifications. The invention is not limited to the scope of those examples.

### Experiments of Surface Modification of Photoresist

99.5 parts by weight of the photoresist (1% of polysiloxane resin, 0.1% of the surfactant of polyoxyethylene compound, 0.005% of nitric acid as pH adjuster, 1% of nitrogen silane compound as curing catalyst, 1% of photo acid as acid generator, the remaining component ratio being solvent, and the solvent being composed of propylene glycol monoethyl ether and water in a weight ratio of 85:15), 0.25 parts by weight of fluorine-containing additive (B-1), and 0.25 parts by weight of polyether polyol (C-1) were mixed, and stirred uniformly with a stirrer to obtain the modified photoresist of Experiment 1.

The modified photoresists of Experiment 2 to Experiment 10 and Comparative Experiment 1 to Comparative Experiment 6 were prepared using the same steps as in Experiment 1, and the difference thereof is: the type of components and the usage amount thereof in the modified photoresist are changed (as shown in Table 2), wherein the components/compounds corresponding to the labels in Table 2 are shown in Table 1. After dropping 10 μL of deionized water on the surface of the prepared modified photoresist, the contact angle between the deionized water and the photoresist surface was measured using a contact angle meter (Model: DropMaster500, manufactured by Kyowa Interface Science Co., Ltd.) to obtain the contact angle, with the results shown in Table 2. When the contact angle is smaller, the photoresist surface has good hydrophilicity, which can provide the photoresist with good adhesion.

TABLE 1

| | Symbol | Component/Compound |
|---|---|---|
| Solvent (A) | A-1 | A mixed solvent composed by mixing |
| | | 40 parts by weight of propylene |
| | | glycol monomethyl ether (PGME) |
| | | and 60 parts by weight of |
| | | n-Butyl Acetate (NBAC). |
| | A-2 | A mixed solvent composed by |
| | | mixing 70 parts by weight of |
| | | propylene glycol monomethyl |
| | | ether (PGME) and 30 parts by |
| | | weight of propylene glycol |
| | | monomethyl ether acetate |
| | | (PGMEA). |
| Fluorine- | B-1 | A polymer represented by |
| containing additive | | Formula (B-1), wherein: |
| (B) | | R¹ represents a methyl group, |
| | | T¹ represents hydrogen, |
| | | a represents 1, |
| | | b represents 1, |
| | | e represents an integer of 2 to 4, |
| | | f represents an integer of 18 to 22, |
| | | g represents an integer of 2 to 4, |
| | | k represents 2. |
| | | The weight average molecular |
| | | weight is about 2300. |
| | B-2 | A polymer represented by Formula |
| | | (B-2), wherein: |
| | | R² represents a methyl group, |
| | | R³ represents a methyl group, |
| | | R⁴ represents a methyl group, |
| | | T² represents hydrogen, |
| | | a represents 1, |
| | | b represents 1, |
| | | e represents an integer of 8 to 12, |
| | | f represents an integer of 1 to 3, |
| | | g represents an integer of 8 to 12, |
| | | k represents 2. |
| | | A weight average molecular weight |
| | | is about 4800. |
| | B-3 | A polymer represented by Formula |
| | | (B-3), wherein: |
| | | R⁵ represents a methyl group, |
| | | R⁶ represents CH₂CF₃, |
| | | R⁷ represents C₁₀H₁₈, |
| | | R⁸ represents C₅O₂H₇, |
| | | m represents an integer of 17 to 23. |
| | | A weight average molecular weight |
| | | is about 4400. |
| | B-4 | A polymer represented by Formula |
| | | (B-4), wherein: |
| | | Y¹ represents C₉F₁₇, |
| | | R⁹ represents hydrogen, |
| | | T³ represents OH, |
| | | j represents an integer of 6 to 18 |
| | | k represents an integer of 3 to 6, |
| | | p represents an integer of 2 to 3. |
| | | A weight average molecular weight |
| | | is about 2800. |
| Polyether Polyol | C-1 | A polymer represented by Formula |
| (C) | | (C-1), wherein: |
| | | R¹⁰ represents a methyl group, |
| | | R¹¹ represents hydrogen, |
| | | Y² represents hydrogen or a |
| | | methyl group, |
| | | Y³ represents hydrogen, |
| | | t represents an integer of 45 to 65, |
| | | u represents an integer of 43 to 63, |
| | | w represents an integer of 47 to 67. |
| | | A weight average molecular weight |
| | | is about 7000. |

TABLE 2

| Component | | Experiment | | | | | | | |
|---|---|---|---|---|---|---|---|---|---|
| (unit: parts by weight) | | 1 | 2 | 3 | 4 | 5 | 6 | 7 | 8 |
| Photoresist | | 99.5 | 98.75 | 99.25 | 98.2 | 97.6 | 98.8 | 98.2 | 99.25 |
| Fluorine- | B-1 | 0.25 | 0.25 | — | — | — | — | — | — |
| containing | B-2 | — | — | 0.15 | 0.6 | 0.6 | — | — | — |
| additive (B) | B-3 | — | — | — | — | — | 0.6 | 0.6 | — |
| | B-4 | — | — | — | — | — | — | — | 0.15 |
| Polyether | C-1 | 0.25 | 1.0 | 0.6 | 1.2 | 1.8 | 0.6 | 1.2 | 0.6 |
| Polyol (C) | | | | | | | | | |
| (B):(C) | | 1:1 | 1:4 | 1:4 | 1:2 | 1:3 | 1:1 | 1:2 | 1:4 |
| Quotient of Ratio of | | 1.0 | 0.25 | 0.25 | 0.5 | 0.33 | 1.0 | 0.5 | 0.25 |
| (B) to (C) | | | | | | | | | |
| Evaluation | Contact | 61.6 | 45.0 | 58.7 | 56.7 | 46.3 | 53.2 | 43.3 | 46.3 |
| results | Angle (°) | | | | | | | | |
| Component | | Experiment | | Comparative Experiment | | | | | |
| (unit: parts by weight) | | 9 | 10 | 1 | 2 | 3 | 4 | 5 | 6 |
| Photoresist | | 99.3 | 99.3 | 99.4 | 99.4 | 99.4 | 99.4 | 99.4 | 100 |
| Fluorine- | B-1 | — | — | 0.6 | — | — | — | — | — |
| containing | B-2 | — | — | — | 0.6 | — | — | — | — |
| additive (B) | B-3 | — | — | — | — | 0.6 | — | — | — |
| | B-4 | 0.3 | 0.4 | — | — | — | 0.6 | — | — |
| Polyether | C-1 | 0.4 | 0.3 | — | — | — | — | 0.6 | — |
| Polyol (C) | | | | | | | | | |
| (B):(C) | | 3:4 | 4:3 | — | — | — | — | — | — |
| Quotient of Ratio of | | 0.75 | 1.33 | — | — | — | — | — | — |
| (B) to (C) | | | | | | | | | |
| Evaluation | Contact | 56.8 | 62.5 | 65.1 | 77.7 | 76.2 | 78.8 | 46.1 | 61.1 |
| results | Angle (°) | | | | | | | | |

As shown in Table 2, compared to the unmodified photoresist (Comparative Experiment 6), the modified photoresists including the polyether polyol (C) with specific structure (Experiments 1 to 10 and Comparative Experiment 5) may have contact angles that are smaller than or substantially equal to that of the unmodified photoresist. Therefore, adding the polyether polyol (C) with specific structure may help improve the hydrophilicity of the photoresist surface, thereby enhancing adhesion.

In addition, compared to the unmodified photoresist (Comparative Experiment 6), the modified photoresists that only include the fluorine-containing additive (B) with specific structure but do not include the polyether polyol (C) with specific structure (Comparative Experiments 1 to 4) have larger contact angle, indicating that they are unfavorable for improving the hydrophilicity and adhesion of the photoresist surface.

In addition, compared to the modified photoresists that only include the fluorine-containing additive (B) with specific structure but do not include the polyether polyol (C) with specific structure (Comparative Experiments 1 to 4), the modified photoresists that include both the fluorine-containing additive (B) with specific structure and the polyether polyol (C) with specific structure (Experiments 1 to 10) have smaller contact angle, indicating that their surfaces may have better hydrophilicity, thereby providing the photoresist with good adhesion.

### Examples of Thinner Composition

Example 1 to Example 8 and Comparative Example 1 to Comparative Example 6 of the thinner compositions are described below:

### Example 1

0.6 parts by weight of the fluorine-containing additive (B-1) and 0.3 parts by weight of the polyether polyol (C-1) were added to 99.1 parts by weight of solvent (A-1) (a mixed solvent composed by mixing 40 parts by weight of propylene glycol monomethyl ether (PGME) and 60 parts by weight of n-butyl acetate (NBAC)), and mixed uniformly with a stirrer to obtain the thinner composition of Example 1.

### Example 2 to Example 8 and Comparative Example 1 to Comparative Example 6

The thinner compositions of Example 2 to Example 8 and Comparative Example 1 to Comparative Example 6 were prepared using the same steps as in Example 1, and the difference thereof is: the type of components and the usage amount thereof in the thinner compositions are changed (as shown in Table 3), wherein the components/compounds corresponding to the labels in Table 3 are shown in Table 1. The obtained thinner compositions were evaluated by each of the following evaluation methods, and the results thereof are as shown in Table 3.

TABLE 3

| Component | | Example | | | | | | | |
|---|---|---|---|---|---|---|---|---|---|
| (unit: parts by weight) | | 1 | 2 | 3 | 4 | 5 | 6 | 7 | 8 |
| Solvent (A) | A-1 | 99.1 | — | 98.8 | 98.2 | — | — | — | — |
| | A-2 | — | 99.4 | — | — | 99.1 | 99.2 | 99.1 | 99.25 |
| Fluorine- | B-1 | 0.6 | — | — | — | — | — | — | — |
| containing | B-2 | — | 0.3 | 0.3 | 0.6 | — | — | — | — |
| additive (B) | B-3 | — | — | — | — | 0.6 | — | — | — |
| | B-4 | — | — | — | — | — | 0.5 | 0.5 | 0.15 |
| Polyether | C-1 | 0.3 | 0.3 | 0.9 | 1.2 | 0.3 | 0.3 | 0.4 | 0.6 |
| Polyol (C) | | | | | | | | | |
| (B):(C) | | 2:1 | 1:1 | 1:3 | 1:2 | 2:1 | 5:3 | 5:4 | 1:4 |
| Quotient of Ratio of (B) | | 2.0 | 1.0 | 0.33 | 0.5 | 2.0 | 1.67 | 1.25 | 0.25 |
| to (C) | | | | | | | | | |
| Evaluation | Adhesion | ◯ | ◯ | ⊚ | ⊚ | Δ | Δ | ◯ | ⊚ |
| results | Protrusion | ◯ | ◯ | ◯ | ◯ | Δ | ⊚ | ⊚ | ⊚ |
| | Removability | | | | | | | | |
| | Cleaning | ◯ | ◯ | ◯ | ◯ | ◯ | ◯ | ◯ | ◯ |
| | effect | | | | | | | | |

| | |
|---|---|
| Component | Comparative Example |

| (unit: parts by weight) | | 1 | 2 | 3 | 4 | 5 | 6 |
|---|---|---|---|---|---|---|---|
| Solvent (A) | A-1 | — | — | — | — | — | — |
| | A-2 | 99.7 | 99.7 | 99.7 | 99.7 | 99.7 | 100 |
| Fluorine- | B-1 | 0.3 | — | — | — | — | — |
| containing | B-2 | — | 0.3 | — | — | — | — |
| additive (B) | B-3 | — | — | 0.3 | — | — | — |
| | B-4 | — | — | — | 0.3 | — | — |
| Polyether | C-1 | — | — | — | — | 0.3 | — |
| Polyol (C) | | | | | | | |
| (B):(C) | | — | — | — | — | — | — |
| Quotient of Ratio of (B) | | — | — | — | — | — | — |
| to (C) | | | | | | | |
| Evaluation | Adhesion | X | X | X | X | ⊚ | ⊚ |
| results | Protrusion | ◯ | ◯ | Δ | ⊚ | X | X |
| | Removability | | | | | | |
| | Cleaning | ◯ | ◯ | ◯ | ◯ | ◯ | ◯ |
| | effect | | | | | | |

### <Evaluation Methods>

a. Adhesion

The prepared thinner composition was sprayed through the nozzle of a coating equipment (Model: MK8, manufactured by Tokyo Power Company) onto the edge of a substrate surface (e. g. a semiconductor wafer) that had been coated with a photoresist composition. Next, baking was performed at a temperature of 220° C. for 60 seconds. Then, after cooling to 23° C., a first photoresist layer was obtained. Subsequently, another photoresist composition was coated on the first photoresist layer. After baking at 220° C. for 60 seconds, and then cooled to 23° C. to obtain a second photoresist layer. The photoresist composition forming the second photoresist layer may be the same as or different from the photoresist composition forming the first photoresist layer. Then, photographs of the substrate with two layers of photoresist layer were taken by using a metallurgical microscope (Model: L200N, manufactured by Nikon Corporation) to observe the distance (d) between an outermost edge of the first photoresist layer and an outermost edge of the second photoresist layer in the direction parallel to the substrate. When the distance between the outermost edges of the two photoresist layers is smaller, the residue of the thinner composition on the edge of the first photoresist layer surface is less, resulting in good adhesion between the second photoresist layer and the first photoresist layer.

The evaluation criteria for adhesion are as follows:

$$: d \leq 200 μm ;$$

$$◦ : 200 μm < d \leq 600 μm ;$$

$$△ : 600 μm < d \leq 1000 μm ;$$

$$\times : 1000 μm < d .$$

b. Protrusion Removal Property

The prepared thinner composition was sprayed through the nozzle of a coating equipment (Model: MK8, manufactured by Tokyo Power Company) onto the edge of a substrate surface (e. g. a semiconductor wafer) that had been coated with a photoresist composition. Subsequently, baking was performed at a temperature of 220° C. for 60 seconds to obtain a photoresist. Then, a probe tip of a thin film thickness profiler (α-step) (Model: 138370, manufactured by Veeco Instruments Inc.) may be used to scan the wafer surface. As the probe scanned across the wafer surface, a sensor recorded the vertical movement changes of the probe. The signal generated by the vertical movement changes of the probe may display a one-dimensional profile of the wafer surface, thereby revealing the topography and uniformity of the wafer surface after coating the photoresist. This method was used to determine the height of the photoresist protrusion at the edge of the wafer. Compared to the height of protrusions at the edge of the substrate surface sprayed with conventional wafer processing liquid, the height of protrusions at the edge of the substrate surface sprayed with the thinner composition prepared in the Examples/Comparative Examples are reduced greater, indicating that the thinner composition has good protrusion removal property.

The evaluation criteria for protrusion removal property are as follows:

$$: 95 \% \leq Reduction ratio of protrusion height at the edge of the substrate surface ;$$

$$◦ : 75 \% \leq Reduction ratio of protrusion \text{} height at the edge of the substrate surface < 95 \% ;$$

$$△ : 50 \% \leq Reduction ratio of protrusion height at the edge of the substrate surface < 75 \% ;$$

$$\times : Reduction ratio of protrusion height at the edge of the substrate surface < 50 \% .$$

c. Cleaning Effect

The prepared thinner composition was sprayed through the nozzle of a coating equipment (Model: MK8, manufactured by Tokyo Power Company) onto the edge of a substrate surface (e. g. a semiconductor wafer) that had been coated with a photoresist composition. Then, the edge of the substrate surface was observed by using a metallurgical microscope (Model: L200N, manufactured by Nikon Corporation). When there is no residue at the edge of the substrate surface, the thinner composition has good cleaning effect.

The evaluation criteria for the cleaning effect are as follows:
∘: No residue at the edge of the substrate surface;
X: Residue at the edge of the substrate surface.

### <Evaluation Results>

As shown in Table 3, when the Examples of the thinner composition including the fluorine-containing additive (B) with a specific structure and the polyether polyol (C) with a specific structure is used in the method for substrate processing, the thinner composition has good adhesion, protrusion removal property, and cleaning effect, and may be applicable to the manufacturing process of semiconductor devices, display devices, or optical elements. In contrast, when the Comparative Examples of the thinner composition that does not include the fluorine-containing additive (B) with a specific structure and/or the polyether polyol (C) with a specific structure is used in the method for substrate processing, the thinner composition has poor adhesion and/or protrusion removal property.

In addition, when the thinner compositions are used in the method for substrate processing, compared to the thinner compositions that do not include the polyether polyol (C) with a specific structure (Comparative Examples 1 to 4), the thinner compositions that include the polyether polyol (C) with a specific structure (Examples 1 to 8) have better adhesion.

In addition, when the thinner compositions are used in the method for substrate processing, compared to the thinner composition that does not incorporate the fluorine-containing additive (B) with a specific structure (Comparative Example 5), the thinner compositions that include the fluorine-containing additive (B) with a specific structure (Examples 1 to 8) have better protrusion removal property.

In addition, when the thinner compositions are used in the method for substrate processing, compared to the thinner composition that includes the polymer represented by Formula (B-3) (Example 5), the thinner compositions that include the polymer represented by Formula (B-1), Formula (B-2), or Formula (B-4) (Examples 1 to 4 and 6 to 8) have better adhesion and/or protrusion removal property.

In addition, when the thinner compositions are used in the method for substrate processing, compared to the thinner compositions that include the polymer represented by Formula (B-1), Formula (B-2), or Formula (B-3) (Examples 1 to 5), the thinner compositions that include the polymer represented by Formula (B-4) (Examples 6 to 8) have excellent protrusion removal property (evaluation result shown by ⊚).

In addition, compared to the thinner compositions wherein the ratio of the usage amount of the fluorine-containing additive (B) to the usage amount of the polyether polyol (C) is not within the range of 1:2 to 1:4 (Examples 1 to 2 and 5 to 7), the thinner compositions wherein the ratio of the usage amount of the fluorine-containing additive (B) to the usage amount of the polyether polyol (C) is within the range of 1:2 to 1:4 (Examples 3 to 4 and 8) have excellent adhesion (evaluation result shown by ⊚) as well as good protrusion removal property and cleaning effect.

Based on the above, when the thinner composition of the invention includes the fluorine-containing additive (B) with a specific structure and the polyether polyol (C) with a specific structure, with their respective usage amounts within specific ranges, and the ratio of the usage amount of the fluorine-containing additive (B) with a specific structure to the usage amount of the polyether polyol (C) with a specific structure is within a specific range, the thinner composition has good adhesion, protrusion removal property, and cleaning effect when used in the method for substrate processing. As a result, it may be applicable to the manufacturing processes of semiconductor devices, display devices, or optical elements, thereby improving the performance of the formed devices or elements. Furthermore, when the modified photoresist of the invention includes the fluorine-containing additive (B) with a specific structure and the polyether polyol (C) with a specific structure, with their respective usage amounts within specific ranges, and the ratio of the usage amount of the fluorine-containing additive (B) with a specific structure to the usage amount of the polyether polyol (C) with a specific structure is within a specific range, the modified photoresist imparts good hydrophilicity to the photoresist surface, resulting in good adhesion, and thus, it may be applicable to the manufacturing processes of semiconductor devices, display devices, or optical elements.

Although the invention has been disclosed in the embodiments above, they are not intended to limit the invention. Anyone with ordinary knowledge in the relevant technical field can make changes and modifications without departing from the spirit and scope of the invention. The scope of protection of the invention shall be subject to those defined by the claims attached.

What is claimed is:

1. A thinner composition, comprising:
a solvent (A);
a fluorine-containing additive (B), comprising a polymer represented by the following Formula (B-1), a polymer represented by the following Formula (B-2), a polymer represented by the following Formula (B-3), a polymer represented by the following Formula (B-4), or a combination thereof; and
a polyether polyol (C), comprising a polymer represented by the following Formula (C-1),
wherein a ratio of a usage amount of the fluorine-containing additive (B) to a usage amount of the polyether polyol (C) is 2:1 to 1:4,
based on 100 parts by weight of the thinner composition, a usage amount of the fluorine-containing additive (B) is 0.001 parts by weight to 2 parts by weight, a usage amount of the polyether polyol (C) is 0.001 parts by weight to 2 parts by weight, 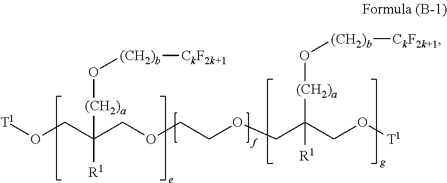
in Formula (B-1), R¹ represents hydrogen, fluorine, a hydroxyl group, an alkyl group with 1 to 3 carbon atoms, or a fluoroalkyl group with 1 to 2 carbon atoms,
T¹ represents hydrogen, an alkyl group with 1 to 3 carbon atoms, *—COCH₃, *—COC₂H₅, *—SO₃H, *—SO₃NH₄, *—SO₃Na or *—SO₃K,
a represents an integer of 1 to 3,
b represents an integer of 1 to 5,
e represents an integer of 1 to 8,
f represents an integer of 10 to 30,
g represents an integer of 2 to 10,
k represents an integer of 1 to 5; 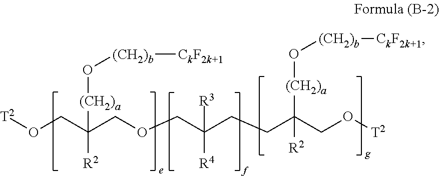
in Formula (B-2), R² represents hydrogen, fluorine, a hydroxyl group, an alkyl group with 1 to 3 carbon atoms, or a fluoroalkyl group with 1 to 2 carbon atoms,
R³ represents hydrogen, a hydroxyl group, a carboxyl group, an alkyl group with 1 to 3 carbon atoms, *—COCH₃, *—COC₂H₅, *—SO₃H, *—SO₃NH₄, *—SO₃Na or *—SO₃K,
R⁴ represents hydrogen, a hydroxyl group, an alkyl group with 1 to 2 carbon atoms, or an alkoxy group with 1 to 2 carbon atoms,
T² represents hydrogen, an alkyl group with 1 to 3 carbon atoms, *—COCH₃, *—COC₂H₅, *—SO₃H, *—SO₃NH₄, *—SO₃Na or *—SO₃K,
a represents an integer of 1 to 3,
b represents an integer of 1 to 5,
f represents an integer of 1 to 20,
k represents an integer of 1 to 6,
a sum of e and g is an integer of 17 to 30; 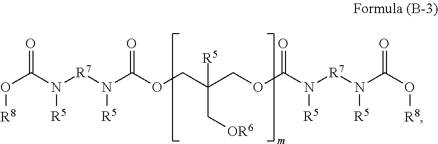
in Formula (B-3), R⁵ represents hydrogen, an alkyl group with 1 to 3 carbon atoms, or an alkoxy group with 1 to 3 carbon atoms,
R⁶ represents a fluoroalkyl group with 1 to 4 carbon atoms,
R⁷ represents CₙH₂ₙ₋₂, wherein n represents an integer of 4 to 20,
R⁸ represents C_{y}H_{2y-3}O_{z}, wherein y represents an integer of 4 to 20, z represents an integer of 0 to 5,
m represents an integer of 2 to 30; 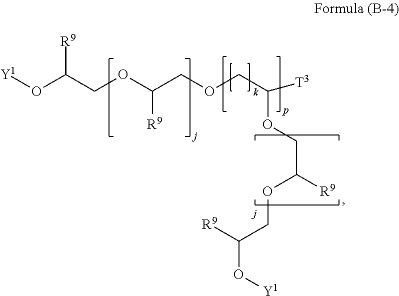
in Formula (B-4), Y¹ represents CᵣF₂ᵣ₋₁, wherein r represents an integer of 2 to 15,
R⁹ represents hydrogen, a hydroxyl group, an alkyl group with 1 to 3 carbon atoms, or an alkoxy group with 1 to 3 carbon atoms,
T³ represents hydrogen, an alkyl group with 1 to 3 carbon atoms, an alkoxy group with 1 to 3 carbon atoms, a hydroxyl group, a carboxyl group, *—COOCH₃, *—COOC₂H₅, an aldehyde group, an amino group, *—OSO₃H, *—OSO₃NH₄, *—OSO₃Na or *—OSO₃K,
j represents an integer of 2 to 30,
k represents an integer of 0 to 20,
p represents an integer of 1 to 9; 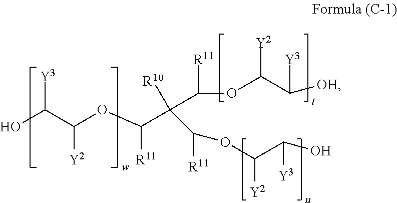
in Formula (C-1), R¹⁰ represents hydrogen, an alkyl group with 1 to 5 carbon atoms, an alkoxy group with 1 to 5 carbon atoms, a hydroxyl group, a carboxyl group, *—COOCH₃, *—COOC₂H₅, an aldehyde group, an amino group, *—OSO₃H, *—OSO₃NH₄, *—OSO₃Na or *—OSO₃K,
R¹¹ represents hydrogen, a hydroxyl group or an alkyl group with 1 to 5 carbon atoms,
Y² represents hydrogen, a hydroxyl group, an alkyl group with 1 to 6 carbon atoms or an alkoxy group with 1 to 6 carbon atoms,
Y³ represents hydrogen, a hydroxyl group, an alkyl group with 1 to 8 carbon atoms or an alkoxy group with 1 to 8 carbon atoms,
t represents an integer of 10 to 600,
u represents an integer of 10 to 700,
w represents an integer of 10 to 800,
wherein * represents a bonding position.

2. The thinner composition as claimed in claim 1, wherein the solvent (A) comprises propylene glycol monomethyl ether, propylene glycol monomethyl ether acetate, n-butyl acetate, N-methyl-2-pyrrolidone, isopropanol, 4-methyl-2-pentanol, γ-butyrolactone, cyclohexanone, cyclohexanol, dimethyl sulfoxide, ethanol, methanol, butanol or a combination thereof.

3. The thinner composition as claimed in claim 1, wherein the solvent (A) is a mixed solvent, the mixed solvent is composed by mixing at least two different organic solvents.

4. The thinner composition as claimed in claim 1, wherein the solvent (A) comprises propylene glycol monomethyl ether, and further comprising at least one of propylene glycol monomethyl ether acetate, n-butyl acetate, N-methyl-2-pyrrolidone, isopropanol, 4-methyl-2-pentanol, γ-butyrolactone, cyclohexanone, cyclohexanol, dimethyl sulfoxide, ethanol, methanol, and butanol.

5. The thinner composition as claimed in claim 1, wherein the solvent (A) is a mixed solvent composed by mixing propylene glycol monomethyl ether and n-butyl acetate, and a mixing ratio of propylene glycol monomethyl ether to n-butyl acetate is 10:90 to 40:60.

6. The thinner composition as claimed in claim 1, wherein the solvent (A) is a mixed solvent composed by mixing propylene glycol monomethyl ether and propylene glycol monomethyl ether acetate, and a mixing ratio of propylene glycol monomethyl ether to propylene glycol monomethyl ether acetate is 50:50 to 80:20.

7. The thinner composition as claimed in claim 1, wherein a weight average molecular weight of the polymer represented by Formula (B-1) is 1000 to 5000, a weight average molecular weight of the polymer represented by Formula (B-2) is 2000 to 9000, a weight average molecular weight of the polymer represented by Formula (B-3) is 1500 to 8500, a weight average molecular weight of the polymer represented by Formula (B-4) is 1000 to 15000.

8. The thinner composition as claimed in claim 1, wherein a weight average molecular weight of the polymer represented by Formula (C-1) is 4000 to 25000.

9. A method for substrate processing, comprising:
applying the thinner composition as claimed in claim 1 to a substrate surface.

10. The method for substrate processing as claimed in claim 9, wherein the thinner composition is applied to an edge of the substrate surface.

11. The method for substrate processing as claimed in claim 9, wherein a photoresist composition has been coated on the substrate surface, and the thinner composition removes a protrusion on an edge of a surface of a photoresist composition.

12. A modified photoresist, comprising:
a photoresist;
a fluorine-containing additive (B), comprising a polymer represented by the following Formula (B-1), a polymer represented by the following Formula (B-2), a polymer represented by the following Formula (B-3), a polymer represented by the following Formula (B-4), or a combination thereof; and
a polyether polyol (C), comprising a polymer represented by the following Formula (C-1),
wherein a ratio of a usage amount of the fluorine-containing additive (B) to a usage amount of the polyether polyol (C) is 2:1 to 1:4,
based on 100 parts by weight of the modified photoresist, a usage amount of the fluorine-containing additive (B) is 0.001 parts by weight to 2 parts by weight, a usage amount of the polyether polyol (C) is 0.001 parts by weight to 2 parts by weight, 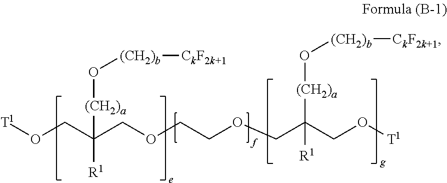
in Formula (B-1), R¹ represents hydrogen, fluorine, a hydroxyl group, an alkyl group with 1 to 3 carbon atoms, or a fluoroalkyl group with 1 to 2 carbon atoms,
T¹ represents hydrogen, an alkyl group with 1 to 3 carbon atoms, *—COCH₃, *—COC₂H₅, *—SO₃H, *—SO₃NH₄, *—SO₃Na or *—SO₃K,
a represents an integer of 1 to 3,
b represents an integer of 1 to 5,
e represents an integer of 1 to 8,
f represents an integer of 10 to 30,
g represents an integer of 2 to 10,
k represents an integer of 1 to 5; 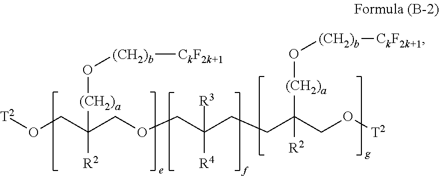
in Formula (B-2), R² represents hydrogen, fluorine, a hydroxyl group, an alkyl group with 1 to 3 carbon atoms, or a fluoroalkyl group with 1 to 2 carbon atoms,
R³ represents hydrogen, a hydroxyl group, a carboxyl group, an alkyl group with 1 to 3 carbon atoms, *—COCH₃, *—COC₂H₅, *—SO₃H, *—SO₃NH₄, *—SO₃Na or *—SO₃K,
R⁴ represents hydrogen, a hydroxyl group, an alkyl group with 1 to 2 carbon atoms, or an alkoxy group with 1 to 2 carbon atoms,
T² represents hydrogen, an alkyl group with 1 to 3 carbon atoms, *—COCH₃, *—COC₂H₅, *—SO₃H, *—SO₃NH₄, *—SO₃Na or *—SO₃K,
a represents an integer of 1 to 3,
b represents an integer of 1 to 5,
f represents an integer of 1 to 20,
k represents an integer of 1 to 6,
a sum of e and g is an integer of 17 to 30; 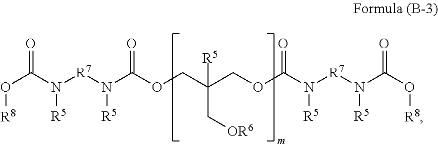
in Formula (B-3), R⁵ represents hydrogen, an alkyl group with 1 to 3 carbon atoms, or an alkoxy group with 1 to 3 carbon atoms,
R⁶ represents a fluoroalkyl group with 1 to 4 carbon atoms,
R⁷ represents CₙH₂ₙ₋₂, wherein n represents an integer of 4 to 20,
R⁸ represents C_{y}H_{2y-3}O_{z}, wherein y represents an integer of 4 to 20, z represents an integer of 0 to 5,
m represents an integer of 2 to 30; 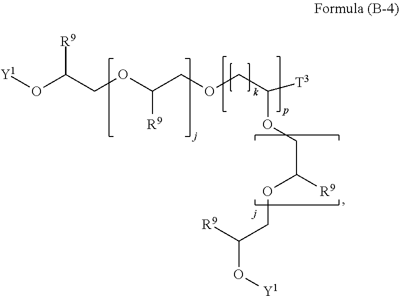
in Formula (B-4), Y¹ represents CᵣF₂ᵣ₋₁, wherein r represents an integer of 2 to 15,
R⁹ represents hydrogen, a hydroxyl group, an alkyl group with 1 to 3 carbon atoms, or an alkoxy group with 1 to 3 carbon atoms,
T³ represents hydrogen, an alkyl group with 1 to 3 carbon atoms, an alkoxy group with 1 to 3 carbon atoms, a hydroxyl group, a carboxyl group, *—COOCH₃, *—COOC₂H₅, an aldehyde group, an amino group, *—OSO₃H, *—OSO₃NH₄, *—OSO₃Na or *—OSO₃K,
j represents an integer of 2 to 30,
k represents an integer of 0 to 20,
p represents an integer of 1 to 9; 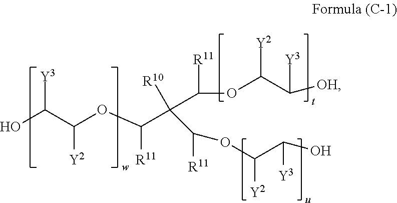
in Formula (C-1), R¹⁰ represents hydrogen, an alkyl group with 1 to 5 carbon atoms, an alkoxy group with 1 to 5 carbon atoms, a hydroxyl group, a carboxyl group, *—COOCH₃, *—COOC₂H₅, an aldehyde group, an amino group, *—OSO₃H, *—OSO₃NH₄, *—OSO₃Na or *—OSO₃K,
R¹¹ represents hydrogen, a hydroxyl group or an alkyl group with 1 to 5 carbon atoms,
Y² represents hydrogen, a hydroxyl group, an alkyl group with 1 to 6 carbon atoms or an alkoxy group with 1 to 6 carbon atoms,
Y³ represents hydrogen, a hydroxyl group, an alkyl group with 1 to 8 carbon atoms or an alkoxy group with 1 to 8 carbon atoms,
t represents an integer of 10 to 600,
u represents an integer of 10 to 700,
w represents an integer of 10 to 800,
wherein * represents a bonding position.

13. The modified photoresist as claimed in claim 12, wherein a weight average molecular weight of the polymer represented by Formula (B-1) is 1000 to 5000, a weight average molecular weight of the polymer represented by Formula (B-2) is 2000 to 9000, a weight average molecular weight of the polymer represented by Formula (B-3) is 1500 to 8500, a weight average molecular weight of the polymer represented by Formula (B-4) is 1000 to 15000.

14. The modified photoresist as claimed in claim 12, wherein a weight average molecular weight of the polymer represented by Formula (C-1) is 4000 to 25000.
